(19) United States
(12) Patent Application Publication
(10) Pub. No.: US 2026/0278189 A1
(43) Pub. Date: Sep. 17, 2026

(54) CONSTRUCTION PLANNING SIMULATION METHOD AND SIMULATION SYSTEM

(71) Applicant: KOMATSU LTD., Tokyo (JP)

(72) Inventor: Jin YOGITA, Tokyo (JP)

(21) Appl. No.: 19/162,442

(22) PCT Filed: Jan. 25, 2024
(86) PCT No.: PCT/JP2024/002239

§ 371 Date: Sep. 5, 2025

(30) Foreign Application Priority Data
Mar. 17, 2023 (JP) 2023-043206

(51) Int. Cl. G06F 30/13

(52) U.S. Cl. CPC G06F 30/13

(57) ABSTRACT

A method simulates construction planning using a plurality of electric work machines at a construction site. The method includes acquiring construction amount data indicating a construction amount at the construction site, acquiring work machine data including an electric power consumption rate of each of the plurality of electric work machines, calculating a required total amount of electric power of the plurality of electric work machines at the construction site, and determining a power supply method from among a plurality of power supply methods of different types for charging the plurality of electric work machines. The calculating is based on the construction amount data and the work machine data. The determining is based on the required total amount of electric power.

### CROSS-REFERENCE TO RELATED APPLICATIONS

This application is a U.S. National stage application of International Application No. PCT/JP2024/002239, filed on Jan. 25, 2024. This U.S. National stage application claims priority under 35 U.S.C. § 119(a) to Japanese Patent Application No. 2023-043206, filed in Japan on Mar. 17, 2023. The entire contents of Japanese Patent Application No. 2023-043206 is hereby incorporated herein by reference.

### BACKGROUND

### Technical Field

The present disclosure relates to a simulation method and a simulation system for construction planning.

Background Art In recent years, electric work machines have come to be used at construction sites. In order to efficiently perform work by using an electric work machine at a construction site, it is desirable to charge the electric work machine at the construction site. Accordingly, for example, Japanese Laid-Open Patent Publication No. 2016-084633 describes that a charged towed vehicle charged by a charging facility is towed to a construction site by a transport vehicle, and power is supplied to an electric work machine by the towed vehicle.

### SUMMARY

However, in a case in which a large number of electric work machines operate at a construction site, a sufficient power supply facility is required. Therefore, in power supply by the towed vehicle as described above, there is a possibility that electric power may be insufficient. In addition, in a case in which a temporary power source connected to a power grid is newly installed at a construction site, a significant cost is required. Accordingly, an appropriate power supply method for electric work machines in accordance with a construction site is required. An object of the present disclosure is to provide a simulation method and a simulation system for construction planning for determining an appropriate power supply method in accordance with a construction site.

A simulation method according to one aspect of the present disclosure is a method for simulating construction planning using a plurality of electric work machines at a construction site. The simulation method includes acquiring construction amount data indicating a construction amount at the construction site, acquiring work machine data including an electric power consumption rate of each of the plurality of electric work machines, calculating a required total amount of electric power of the plurality of electric work machines at the construction site, based on the construction amount data and the work machine data, and determining a power supply method, from among a plurality of power supply methods of different types for charging the plurality of electric work machines, based on the required total amount of electric power.

A simulation system according to another aspect of the present disclosure is a simulation system for construction planning using a plurality of electric work machines at a construction site. The simulation system includes a first data acquisition unit, a second data acquisition unit, an electric power calculation unit, and an electric power supply determination unit. The first data acquisition unit acquires construction amount data indicating a construction amount at the construction site. The second data acquisition unit acquires work machine data including an electric power consumption rate of each of the plurality of electric work machines. The electric power calculation unit calculates a required total amount of electric power of the plurality of electric work machines at the construction site, based on the construction amount data and the work machine data. The electric power supply determination unit determines a power supply method, from among a plurality of power supply methods of different types for charging the plurality of electric work machines, based on the required total amount of electric power.

According to the present disclosure, the power supply method is determined based on the required total amount of electric power for the plurality of electric work machines at the construction site. Thus, the appropriate power supply method in accordance with the construction site can be determined.

### BRIEF DESCRIPTION OF DRAWINGS

Referring now to the attached drawings which form a part of this original disclosure, an illustrative embodiment is shown.

FIG. 1 is a diagram illustrating a configuration of a simulation system according to an embodiment.

FIG. 2 is a diagram illustrating an example of a construction site and work machines.

FIG. 3 is a flowchart illustrating processing for simulation of construction planning.

FIG. 4 is a diagram illustrating an example of existing topography and design topography of the construction site.

FIG. 5 is a diagram illustrating an example of a setting screen for a simulation of construction planning.

FIG. 6 is a diagram illustrating an example of operation status data indicating an expected operation status of work machines.

FIG. 7 is a diagram illustrating a power supply method using a “temporary power source”.

FIG. 8 is a diagram illustrating a power supply method using a “portable storage battery”.

FIG. 9 is a diagram illustrating a power supply method using a “portable generator”.

FIG. 10 is a diagram illustrating a power supply method using “battery replacement”.

### DETAILED DESCRIPTION OF EMBODIMENT(S)

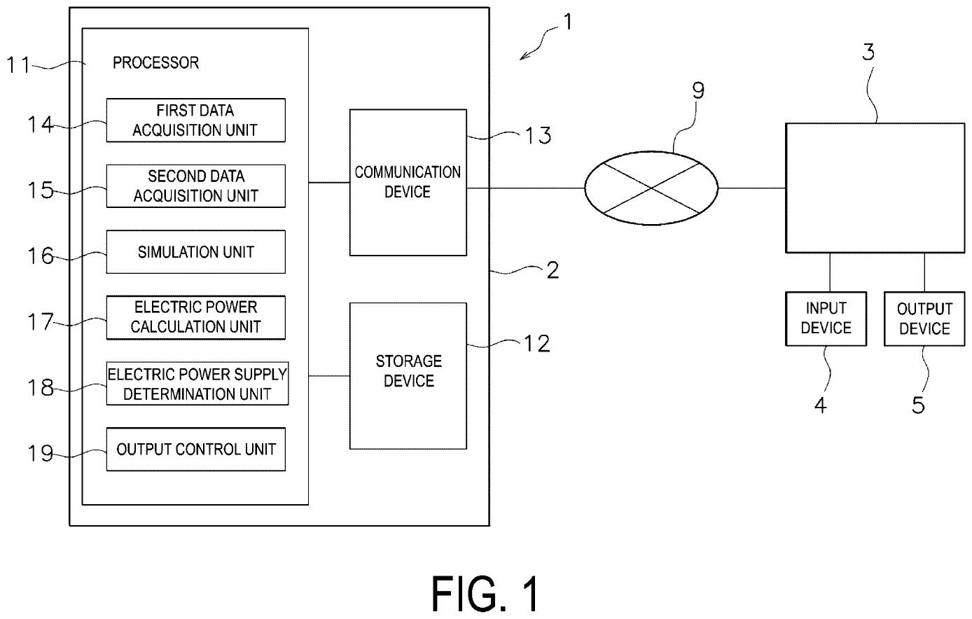

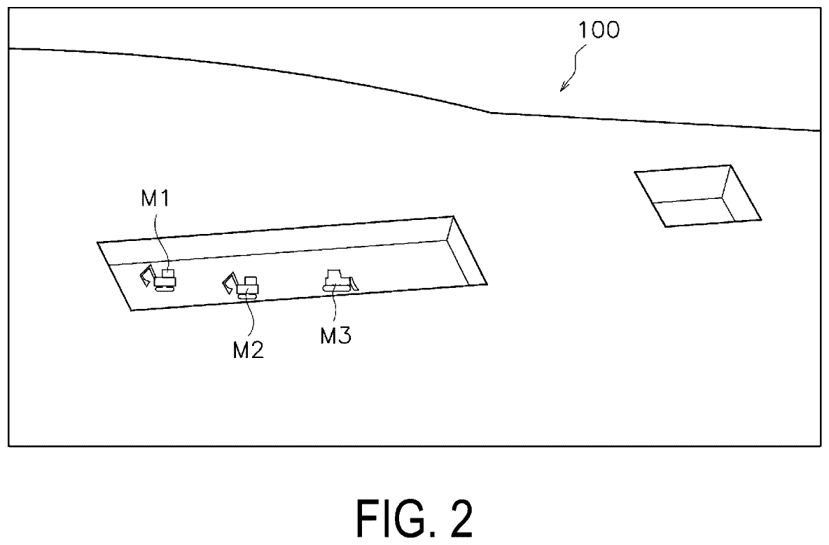

Hereinafter, an embodiment of the present disclosure will be described with reference to the accompanying drawings. FIG. 1 is a diagram illustrating a configuration of a simulation system 1 according to an embodiment. As illustrated in FIG. 2, the simulation system 1 performs a simulation of construction planning using a plurality of work machines M1 to M3 at a construction site 100.

The work machines M1 to M3 perform work at the construction site 100. The work machines M1 to M3 include construction machines that can perform pushing or excavation of earth and sand, and/or transport vehicles that can transport earth and sand. The construction machines include, for example, a shovel and/or a bulldozer. The transport vehicles include a dump truck. Note that the construction machines may be a wheel loader or a motor grader. Note that the work machines M1 to M3 are an example of a plurality of electric work machines. The number of the plurality of electric work machines is not limited to three. The number of the plurality of electric work machines may be greater than three or less than three.

As illustrated in FIG. 1, the simulation system 1 includes a server computer 2. The server computer 2 includes a processor 11, a storage device 12, and a communication device 13. The processor 11 is, for example, a central processing unit (CPU), and executes processing for the simulation of construction planning. The storage device 12 includes a non-volatile memory such as a read only memory (ROM) or a flash memory, and a volatile memory such as a random access memory (RAM). The storage device 12 may include auxiliary storage devices such as a hard disc drive (HDD) or a solid state drive (SSD). The storage device 12 stores a program and data for the simulation of construction planning. The processor 11 executes processing for the simulation of construction planning in accordance with the program and the data.

The communication device 13 performs communication with external devices of the server computer 2. The communication device 13 is connected to an external client computer 3 via a communication network 9 such as the Internet. The configuration of the client computer 3 is similar to that of the server computer 2. The client computer 3 is connected to an input device 4 and an output device 5.

The input device 4 is operable by a user. The input device 4 generates input data in accordance with an operation by the user. The input data generated by the input device 4 is transmitted from the client computer 3 to the server computer 2. The input device 4 includes, for example, a touch screen. The input device 4 may include a keyboard. The input device 4 may include a pointing device such as a mouse. The output device 5 is, for example, a display, and displays an image in accordance with an output signal from the client computer 3. The output device 5 may, alternatively, be a printer.

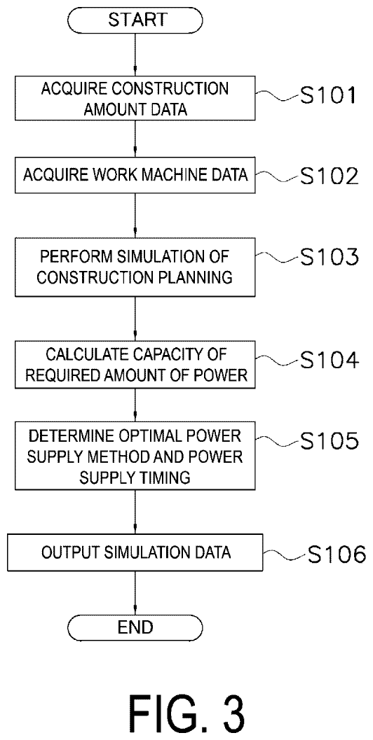

Next, processing for the simulation of construction planning executed by the processor 11 will be described. As illustrated in FIG. 1, the processor 11 includes a first data acquisition unit 14, a second data acquisition unit 15, a simulation unit 16, an electric power calculation unit 17, an electric power supply determination unit 18, and an output control unit 19. The first data acquisition unit 14, the second data acquisition unit 15, the simulation unit 16, the electric power calculation unit 17, the electric power supply determination unit 18, and the output control unit 19 are implemented by the processor 11. FIG. 3 is a flowchart illustrating processing for the simulation of construction planning.

As illustrated in FIG. 3, in step S101, the first data acquisition unit 14 acquires construction amount data. The construction amount data indicates a construction amount at the construction site 100. The construction amount data is transmitted from the client computer 3 to the server computer 2. For example, the construction amount data includes existing topography data and design topography data.

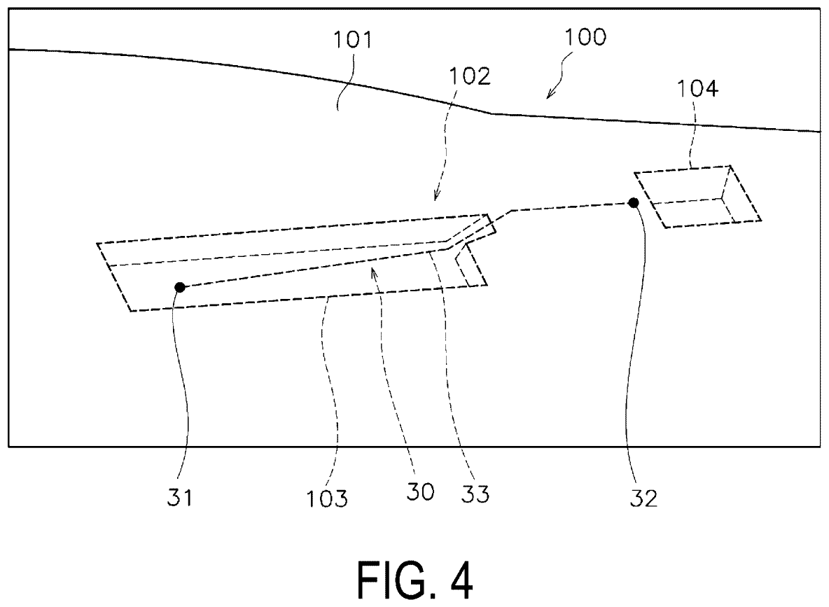

As illustrated in FIG. 4, the existing topography data indicates existing topography 101 of the construction site 100. The existing topography data is three-dimensional topography data indicating a shape of the existing topography 101. The existing topography data is acquired by, for example, a camera mounted on an unmanned aerial vehicle. Alternatively, the existing topography data may be acquired by a measurement device such as a stereo camera or a light detection and ranging (LIDAR) device mounted on a work machine at the construction site 100.

The design topography data indicates design topography 102 of the construction site 100. The design topography data is three-dimensional topography data indicating a shape of the design topography 102. The design topography data is created, for example, by a construction company. As illustrated in FIG. 4, the design topography 102 includes a plurality of work areas 103 and 104 that are partitioned from each other. The work areas 103 and 104 indicate areas in which work is performed by work machines.

The work areas 103 and 104 include a first area 103 and a second area 104. The design topography 102 may include three or more areas that are partitioned from each other. For example, the first area 103 is a cut area described later. The cut area indicates a range in which excavation of earth and sand is performed at the construction site 100. For example, the second area 104 is a fill area. The fill area indicates a range in which fill work is performed at the construction site 100.

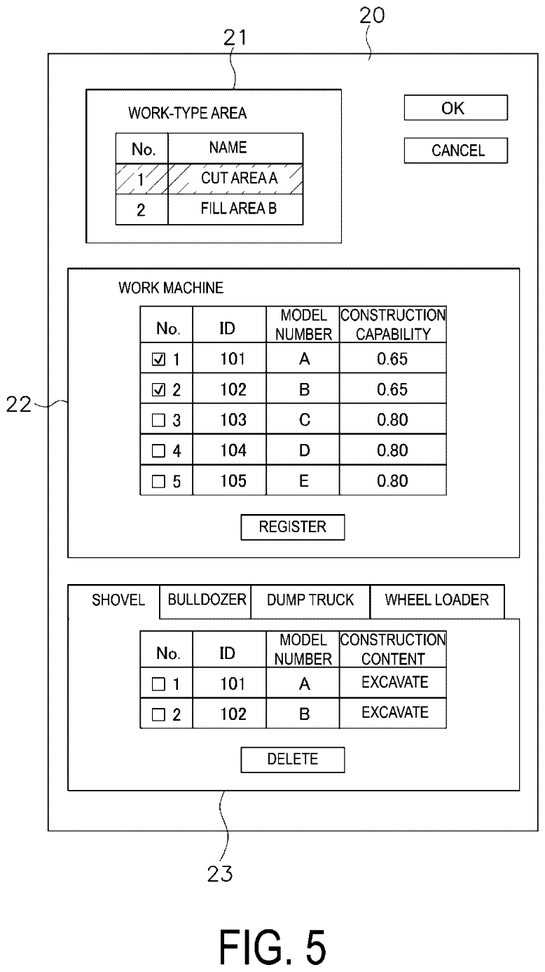

In step S102, the second data acquisition unit 15 acquires work machine data. The work machine data indicates work machines allocated to respective work areas 103 and 104 of the construction site 100. FIG. 5 is a diagram illustrating an example of a setting screen 20 for the simulation of construction planning. The output control unit 19 generates an output signal for causing the setting screen 20 to be displayed on the output device 5, and transmits the output signal to the client computer 3. The output device 5 displays the setting screen 20 in accordance with an output signal from the server computer 2. An operator of the client computer 3 inputs a setting for the simulation of construction planning on the setting screen 20 by using the input device 4.

As illustrated in FIG. 5, the setting screen 20 includes a work-type area list 21, a work machine list 22, and an allocation list 23. The work-type area list 21 indicates a list of work areas 103 and 104 included in the construction site 100. For example, as illustrated in FIG. 5, the work-type area list 21 includes a “cut area A” and a “fill area B”. The operator selects a work area to which a work machine is to be allocated from the work-type area list 21.

The work machine list 22 indicates a list of work machines allocatable to respective work areas. The work machine list 22 includes identification numbers (ID), model numbers, and construction capabilities of work machines. The identification number is a unique number allocated to respective work machines. The model number indicates a type of the work machine. The construction capability indicates an amount of work per unit time. For example, the construction capability of a shovel may be a loading amount, a cut amount, or a fill amount per unit time. Alternatively, the construction capability of the shovel may be determined based on a capacity of a bucket. The construction capability of a bulldozer may be a dozing amount or a fill amount per unit time. The construction capability of the bulldozer may be determined based on a size of a blade. The construction capability of a dump truck may be a transport amount per unit time.

The operator determines, on the setting screen 20, a work machine to be allocated to respective work areas from among work machines included in the work machine list 22. The allocation list 23 indicates a list of work machines allocated to respective work areas. The operator designates construction content by work machines allocated to respective work areas.

The construction content indicates, for example, content of work performed by work machines, such as “excavation” or “fill”.

For example, as illustrated in FIG. 5, a shovel A having ID “101” and a shovel B having ID “102” are allocated to cut area A, and “excavation” is set as construction content for the shovels A and B.

Further, as illustrated in FIG. 4, the operator can set a travel route 30 of a dump truck at the construction site 100. For example, the operator designates, on a screen indicating the construction site 100, a start point 31, a target point 32, and a route 33 connecting the start point 31 and the target point 32. The content set on the setting screen 20 as described above is transmitted, as work machine data, from the client computer 3 to the server computer 2.

In step S103, the simulation unit 16 performs the simulation of construction planning based on the construction amount data and the work machine data. The simulation result of construction planning includes an expected operation status of work machines. The simulation unit 16 calculates a construction amount from the construction amount data. For example, the simulation unit 16 calculates the construction amount from a difference between the existing topography 101 and the design topography 102. The construction amount is indicated, for example, by a volume of soil. The simulation unit 16 calculates the expected operation status of work machines based on the construction amount and the work machine data.

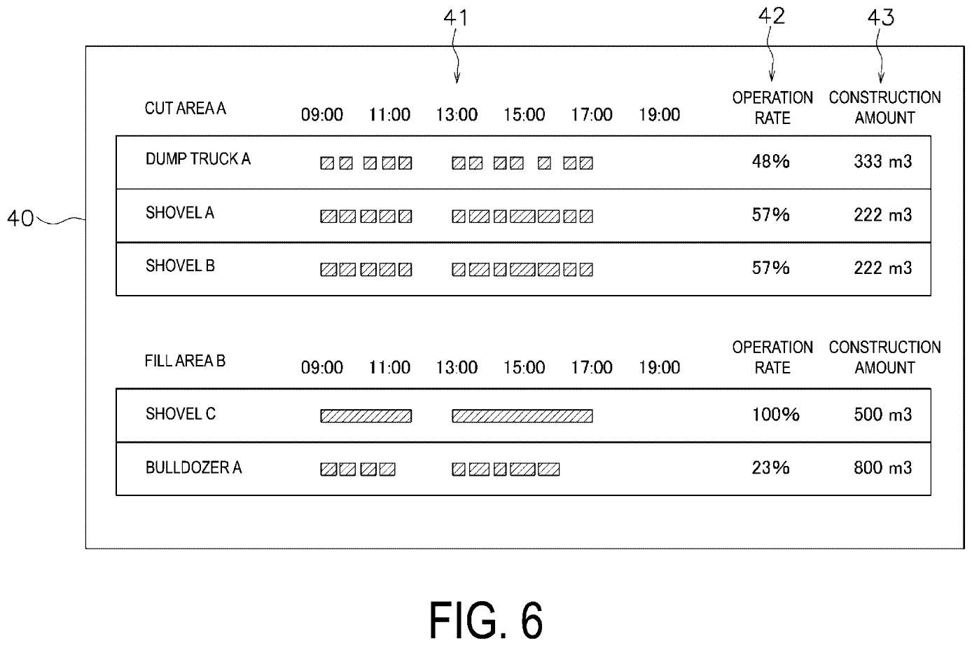

FIG. 6 is a diagram illustrating an example of operation status data 40 indicating the expected operation status of work machines. As illustrated in FIG. 6, the operation status data 40 indicates the expected operation status of work machines allocated to respective work areas. The operation status data 40 includes an operation time 41 in a day of each work machine. The operation time 41 is illustrated, for example, in a graph. The operation status data 40 includes an operation rate 42 of each work machine. The operation rate 42 indicates, for example, a ratio of a time during which each work machine is actually operating to an operation time in a day. The operation status data 40 includes a construction amount 43 of each work machine. The construction amount 43 is indicated, for example, by the volume of soil worked by each work machine in a day.

Note that the simulation result of construction planning may include a period and a cost required for the construction. For example, the simulation unit 16 calculates a period required for the construction based on the construction amount 43, the construction capability of each work machine, and the operation rate 42. The simulation unit 16 calculates the cost required for the construction based on usage fees of work machines, fuel costs, and a period required for the construction.

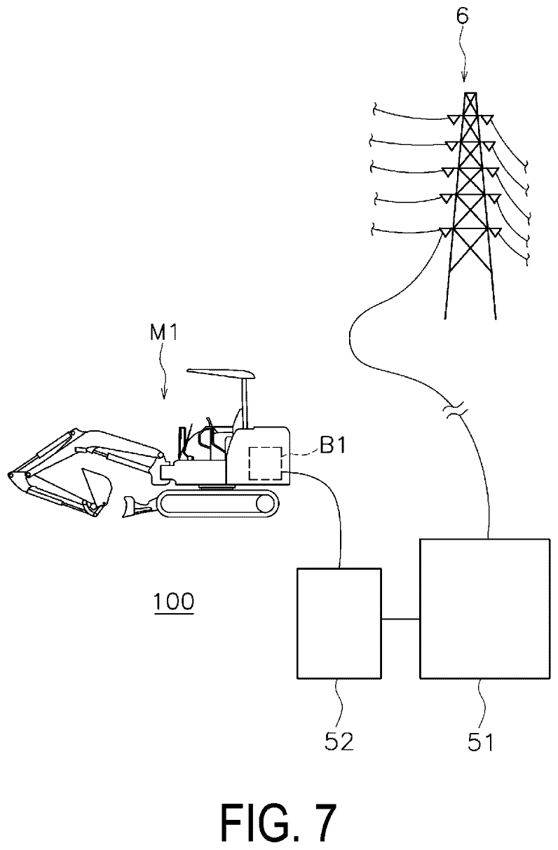

In step S104, the electric power calculation unit 17 calculates a daily required total amount of electric power within the construction period. For example, as illustrated in FIG. 7, the work machine M1 includes a battery B1. The work machine MI is driven by electric power from the battery B1. Other work machines are also driven by electric power of batteries, similarly to the work machine M1. The work machine data described above includes an electric power consumption rate of each of the plurality of work machines allocated to respective work areas. The electric power consumption rate indicates electric power consumed by the work machine per unit time. Alternatively, the electric power consumption rate may indicate electric power consumed by the work machine per unit of work amount. The electric power calculation unit 17 calculates a required total amount of electric power for the plurality of work machines at the construction site 100 based on data of the construction amount 43 and the work machine data.

In step S105, the electric power supply determination unit 18 determines the optimal power supply method and a power supply timing for charging the plurality of work machines.

The electric power supply determination unit 18 determines the optimal power supply method and the power supply timing, based on a required total amount of electric power, from among a plurality of power supply methods of respective different types for charging the plurality of work machines.

The plurality of power supply methods include power supply methods using a “temporary power source”, a “portable storage battery”, a “portable generator”, and “battery replacement”. The power supply method using the “temporary power source” is, as illustrated in FIG. 7, to install a temporary power source 51 at the construction site 100 and to charge the plurality of work machines with use of the temporary power source 51. The temporary power source 51 is connected to a power grid 6 and includes a transformer facility. The temporary power source 51 is connected to the work machine M1 via a charging device 52.

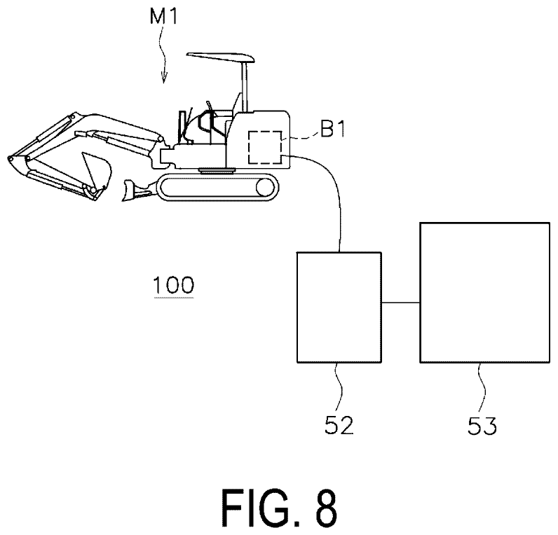

As illustrated in FIG. 8, the power supply method using the “portable storage battery” is to transport a charged portable storage battery 53 to the construction site 100 and to charge the plurality of work machines with use of the portable storage battery 53. The portable storage battery 53 is charged at a charging base provided with a charging facility located remotely from the construction site 100, for example, and then transported to the construction site 100.

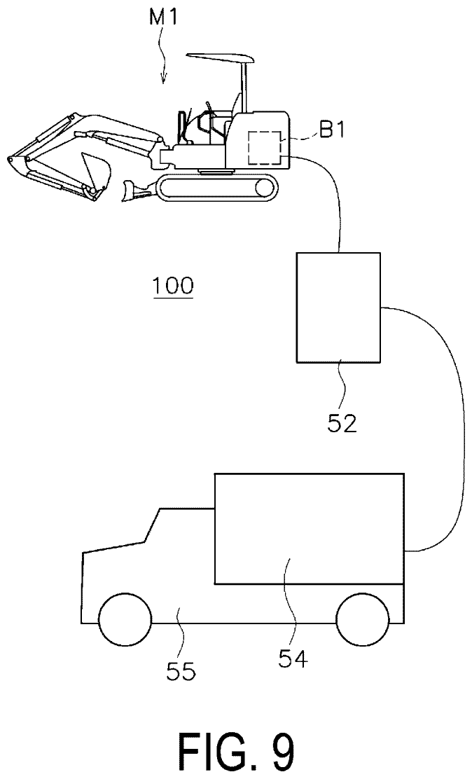

As illustrated in FIG. 9, the power supply method using the “portable generator” is to transport the portable generator 54 to the construction site 100 and to charge the plurality of work machines with use of the portable generator 54. The portable generator 54 may be mounted on a vehicle 55. Alternatively, the portable generator 54 may be unloaded from the vehicle 55 and installed at the construction site 100. Similarly, the “portable storage battery 53” may be mounted on the vehicle 55, or may be unloaded from the vehicle 55 and installed at the construction site 100.

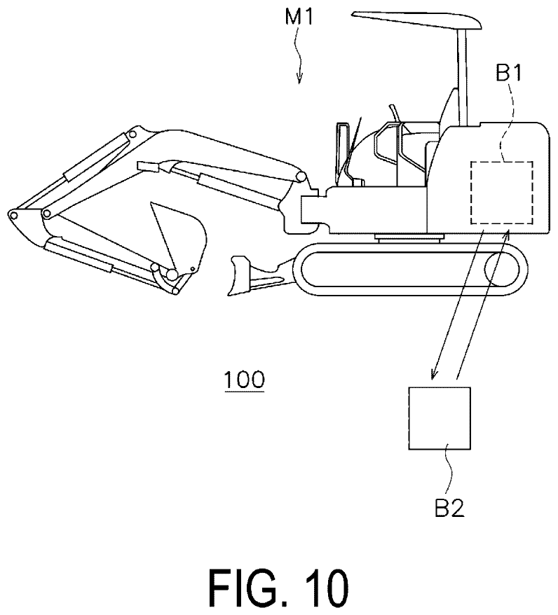

As illustrated in FIG. 10, the power supply method using “battery replacement” is to transport a charged battery B2 to the construction site 100 and to replace the used battery B1 of the work machine M1 with the charged battery B2. The charged battery B2 is transported to the construction site 100 after being charged, for example, at a charging base provided with a charging facility located remotely from the construction site 100.

The electric power supply determination unit 18 calculates the cost of each of the plurality of power supply methods with respect to the required total amount of electric power. For example, the cost of the power supply method using the “temporary power source” is calculated based on an installation cost and a usage fee of the temporary power source 51 and an electricity charge with respect to the required total amount of electric power. The cost of the power supply method using the “portable storage battery” is calculated based on a transportation cost and a usage fee of the portable storage battery 53 and an electricity charge with respect to the required total amount of electric power. The cost of the power supply method using the “portable generator” is calculated based on a transportation cost and a usage fee of the portable generator 54, and an electricity charge with respect to the required total amount of electric power. The cost of the power supply method using “battery replacement” is calculated based on a transportation cost and a usage fee of the replacement battery, and an electricity charge with respect to the required total amount of electric power.

The electric power supply determination unit 18 determines the optimal power supply method based on the cost of each of the plurality of power supply methods. For example, the electric power supply determination unit 18 determines, as the optimal power supply method, the power supply method with the lowest cost among the plurality of power supply methods.

Further, the electric power supply determination unit 18 determines the optimal power supply timing for each electric work machine based on the daily required amount of electric power and the electric power consumption rate of the electric work machine.

The output control unit 19 outputs simulation data indicating a simulation result of construction planning. The output control unit 19 transmits the simulation data to the client computer 3. The simulation data includes the above-described operation status data 40. The output device 5 displays an operation status screen indicating the operation status data 40. The simulation data includes the optimal power supply method. The output device 5 displays a power supply proposal screen indicating the optimal power supply method and the power supply timing. The power supply proposal screen includes, for example, a power supply date, a target machine (ID or model number) for power supply, and a power supply method. The power supply proposal may include the required amount of electric power and the cost. The power supply proposal screen allows easy recognition of when and which power supply facility should be arranged for which electric work machine, and what level of cost will be required.

In the simulation system 1 according to the present embodiment described above, the optimal power supply method is determined based on the required total amount of electric power for the plurality of work machines at the construction site 100. Accordingly, the appropriate power supply method in accordance with the construction site 100 can be determined. For example, installation of the temporary power source 51 may take a long time due to reasons such as requiring an application to a power company that manages the power grid 6. However, according to the simulation system 1 of the present embodiment, necessity of installation of the temporary power source 51 can be determined in advance. Accordingly, arranging installation of the temporary power source 51 before commencement of the construction becomes easier. In addition, since the optimal power supply timing for each electric work machine is determined, a timing for arranging the power supply facility can be easily determined.

Although one embodiment of the present invention has been described above, the present invention is not limited to the above-described embodiment, and various modifications can be made without departing from the gist of the invention.

Processing by the server computer 2 described above may be executed by the client computer 3. The processing by the server computer 2 described above may be executed in a distributed manner by a plurality of computers. The power supply method is not limited to that of the above embodiment and may be modified.

According to the present invention, an appropriate power supply method in accordance with a construction site is determined by a simulation method and a simulation system for construction planning.

1. A method for simulating construction planning using a plurality of electric work machines at a construction site, the method comprising:
acquiring construction amount data indicating a construction amount at the construction site;
acquiring work machine data including an electric power consumption rate of each of the plurality of electric work machines;
calculating a required total amount of electric power of the plurality of electric work machines at the construction site, based on the construction amount data and the work machine data; and
determining a power supply method from among a plurality of power supply methods of different types for charging the plurality of electric work machines, based on the required total amount of electric power.

2. The method according to claim 1, wherein
the plurality of power supply methods include installing, at the construction site, a temporary power source connected to a power grid and charging the plurality of electric work machines with the temporary power source.

3. The method according to claim 1, wherein
the plurality of power supply methods include transporting a portable storage battery having been charged to the construction site and charging the plurality of electric work machines with the portable storage battery.

4. The method according to claim 1, wherein
the plurality of power supply methods include transporting a portable generator to the construction site and charging the plurality of electric work machines with the portable generator.

5. The method according to claim 1, wherein
the plurality of electric work machines include a battery being detachable, and
the plurality of power supply methods include replacement of the battery.

6. The method according to claim 1, wherein
a cost of each of the plurality of power supply methods with respect to the required total amount of electric power is calculated, and
the power supply method is determined based on the cost of each of the plurality of power supply methods.

7. The method according to claim 1, further comprising:
determining a power supply timing for each of the plurality of electric work machines, based on a required amount of electric power and the electric power consumption rate of each of the plurality of electric work machines.

8. A simulation system for construction planning using a plurality of electric work machines at a construction site, the simulation system comprising:
a first data acquisition unit configured to acquire construction amount data indicating a construction amount at the construction site;
a second data acquisition unit configured to acquire work machine data including an electric power consumption rate of each of the plurality of electric work machines;
an electric power calculation unit configured to calculate a required total amount of electric power of the plurality of electric work machines at the construction site, based on the construction amount data and the work machine data; and
an electric power supply determination unit configured to determine a power supply method from among a plurality of power supply methods of different types for charging the plurality of electric work machines, based on the required total amount of electric power.

9. The simulation system according to claim 8, wherein
the plurality of power supply methods include installing, at the construction site, a temporary power source connected to a power grid and charging the plurality of electric work machines with the temporary power source.

10. The simulation system according to claim 8, wherein
the plurality of power supply methods include transporting a portable storage battery having been charged to the construction site and charging the plurality of electric work machines with the portable storage battery.

11. The simulation system according to claim 8, wherein
the plurality of power supply methods include transporting a portable generator to the construction site and charging the plurality of electric work machines with the portable generator.

12. The simulation system according to claim 8, wherein
the plurality of electric work machines include a battery being detachable, and
the plurality of power supply methods include replacement of the battery.

13. The simulation system according to claim 8, wherein
the electric power supply determination unit is configured to
calculate a cost of each of the plurality of power supply methods with respect to the required total amount of electric power, and
determine the power supply method based on the cost of each of the plurality of power supply methods.

14. The simulation system according to claim 8, wherein
the electric power supply determination unit determines a power supply timing for each of the plurality of electric work machines, based on a required amount of electric power and the electric power consumption rate of each of the plurality of electric work machines.
